(19) United States
(12) Patent Application Publication
(10) Pub. No.: US 2014/0253167 A1
(43) Pub. Date: Sep. 11, 2014

(54) MEMORY CHIP TESTING SYSTEM AND CONNECTOR THEREOF

(71) Applicants: Hon Hai Precision Industry Co., Ltd., New Taipei (TW); Hong Fu Jin Precision Industry (ShenZhen) Co., Ltd., Shenzhen (CN)

(72) Inventor: FA-SHENG HUANG, Shenzhen (CN)

(21) Appl. No.: 13/913,523

(22) Filed: Jun. 10, 2013

(30) Foreign Application Priority Data
Mar. 11, 2013 (CN) 2013100757835

(51) Int. Cl. G01R 1/04; H01R 4/48; H05K 7/10

(52) U.S. Cl. CPC G01R 1/0416; H05K 7/1023; H01R 4/48
USPC 324/756.05; 439/68; 439/78

(57) ABSTRACT

A memory chip testing system includes a computer, a rheostat, a voltmeter, and a connector. The computer includes a main board, a number of memory chip interfaces mounted on the main board. The computer runs a testing software to test the stability of a memory chip under different working voltages. The connector includes an insulating substrate and a number of conductive posts. The posts with ends fixed in the insulating substrate and arranged according to the pins of the memory chip interface. The connecter is connected to the pins of one of the number of the memory chip interfaces when testing a memory chip. The rheostat and the voltmeter are electrically connected to selected conductive posts on the insulating substrate, the rheostat adjusts the work voltage of the memory chip, and the voltmeter indicates the work voltage of the memory chip.

### BACKGROUND

1. Technical Field

Embodiments of the present disclosure relate to computer memory testing systems and, particularly, to a computer memory chip testing system with a connector for connecting to a memory chip interface.

2. Description of Related Art

The data accessing rates of computer memory chips are growing fast, and the stability of data accessing is an important factor in assessing the quality of a memory chip. For computer makers, the stability of data accessing under different voltages is tested to evaluate the quality of a memory chip. Memory chips on a mainboard can be tested one by one by soldering wires of test equipment such as a rheostat or a voltmeter to testing pins on the memory chips. After testing, the wires are removed. Nevertheless, during the process of soldering and removing the wires, the mainboard may be damaged.

### BRIEF DESCRIPTION OF THE DRAWINGS

FIG. 1 is a block diagram of a memory chip testing system according to one embodiment of the present invention, together with a memory chip under test.

FIG. 2 is a schematic stereogram of a connector of the memory chip testing system of FIG. 1.

FIG. 3 is a schematic, cross-sectional view of certain parts of the memory chip testing system of FIG. 1, together with the memory chip under test.

### DETAILED DESCRIPTION

The disclosure, including the accompanying drawings in which like reference numerals indicate similar elements, is illustrated by way of example and not by way of limitation. It should be noted that references to “an” or “one” embodiment in this disclosure are not necessarily to the same embodiment, and such references can mean “at least one.”

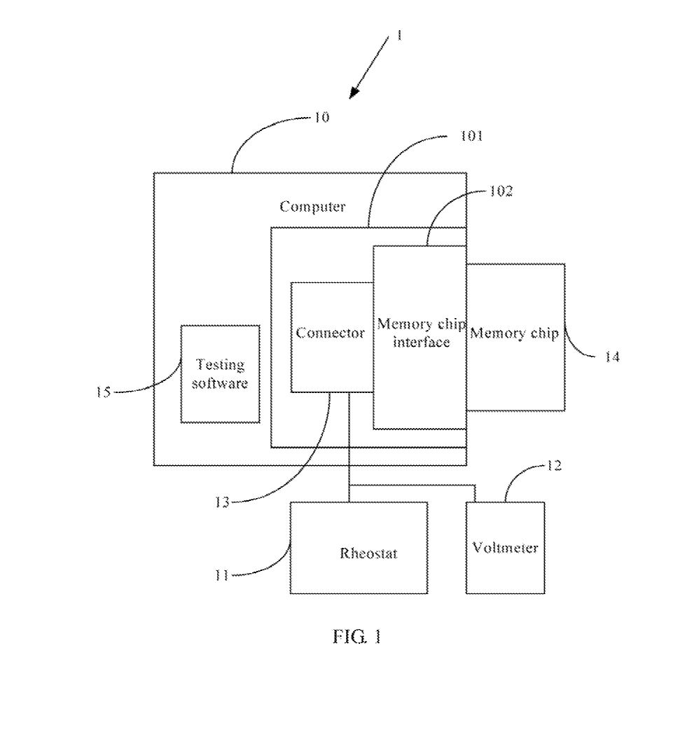

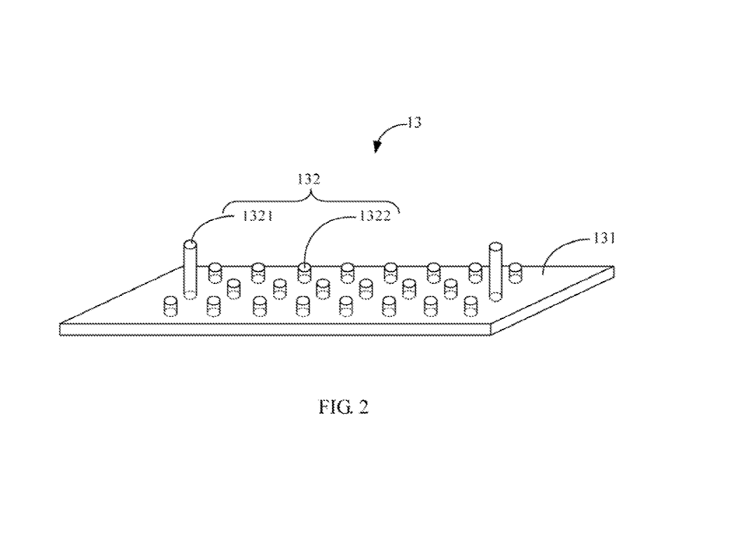

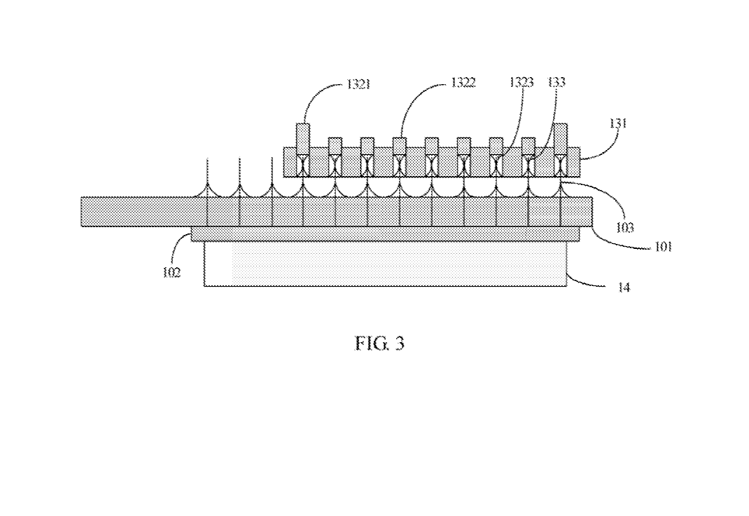

Referring to FIGS. 1-3, a memory chip testing system 1 includes a computer 10, a rheostat 11, a voltmeter 12, and a connector 13. The computer 10 includes a mainboard 101 and a memory chip interface 102. The memory chip interface 102 is mounted on a front of the mainboard 101, and is used to connect to a memory chip 14 needing testing. The computer 10 can then run testing software 15 and test the stability of the memory chip 14 under different working voltages. The connector 13 is used to connect with pins 103 of the memory chip interface 102, the pins 103 projecting from a back of the mainboard 101. The rheostat 11 and the voltmeter 12 are electrically connected to the connector 13, and further connected to the memory chip interface 102 through the connector 13. The rheostat 11 is used to adjust the working voltage of the memory chip 14. In particular, the rheostat 11 is configured to provide different resistances to cause different voltages to apply to the memory chip 14. The voltmeter 12 is used to measure the current working voltage of the memory chip 14.

Note that even though FIG. 1 shows only a single memory chip interface 102 having a memory chip 14 connected thereto, in practice, it is common for the mainboard 101 to have two or more memory chip interfaces 102, with each memory chip interface 102 having a respective memory chip 14 connected thereto.

The connector 13 includes an insulating substrate 131 and a number of conductive posts 132. The conductive posts 132 are partly fixed in the insulating substrate 131 and arranged according to the pins 103 of the memory chip interface 102. In particular, each of the conductive posts 132 corresponds to a pin 103 of the memory chip interface 102. The conductive posts 132 include a number of first conductive posts 1321 and a number of second conductive posts 1322. The first conductive posts 1321 are taller than the second conductive posts 1322. The first conductive posts 1321 are used to connect to the rheostat 11 and the voltmeter 12. A portion of each of the conductive posts 132 that is fixed in the insulating substrate 131 includes an open-ended hollow tube 1323. A pair of elastic strips 133 are set in the open-ended hollow tube 1323. In the embodiment, each of the elastic strips 133 is arcuate, and the elastic strips 133 abut against each other.

In the embodiment, the second conductive posts 1322 are used for stabilizing the connection between the connector 13 and the pins 103 of the memory chip interface 102, thereby preventing the pins 103 of the memory chip interface 102 from being damaged when connecting the connector 13 to the pins 103 of the memory chip interface 102. In other embodiments, the second conductive posts 1322 can be omitted from the connector 13, and only the first conductive posts 1321 used. In other embodiments, the first conductive posts 1321 and the second conductive posts 1322 of the connector 13 may have the same height, so that the connector 13 can be used to test different types of memory chips 14 whose functional pins have different arrangements.

In use of the memory chip testing system 1, the connector 13 is maneuvered so that the open ends of the open-ended hollow tubes 1323 are aligned with and receive the pins 103 of the memory chip interface 102. The arcuate elastic strips 133 in the open-ended hollow tubes 1323 clamp the pins 103 of the memory chip interface 102, thereby firmly connecting the connector 13 to the pins 103 of the memory chip interface 102. During testing a memory chip 14, the rheostat 11 and voltmeter 12 are connected to the corresponding first conductive posts 1321 on the connector 13, instead of being soldered to certain of the pins 103 of the memory chip interface 102. The connector 13 is easily detached from the memory chip interface 102 having the memory chip 14, and easily connected to a next memory chip interface 102 having a next memory chip 14 needing testing. Typically, the next memory chip interface 102 having the next memory chip 14 is on the same mainboard 101 as the first memory chip interface 102 having the first memory chip 14. With the above structure, there is no need for a process of soldering wires and later removing the wires from the pins 103 of the memory chip interface 102. Thereby, damage to the mainboard 101 is avoided.

Although certain embodiments have been specifically described, the present disclosure is not to be construed as being limited thereto. Various changes or modifications may be made to the present embodiments without departing from the scope and spirit of the present disclosure.

What is claimed is:

1. A memory chip testing system comprising:
a rheostat configured to be electrically coupled with a memory chip under test and provide different resistances to cause different voltages to apply to the memory chip;
a voltmeter configured to measure a working voltage of the memory chip; and
a computer comprising:
a mainboard;
a memory chip interface mounted on a front of the mainboard and comprising a plurality of pins projecting from a back of the mainboard, the memory chip interface configured to connect with the memory chip; and
a connector comprising:
an insulating substrate; and
a plurality of conductive posts secured to the insulating substrate and arranged corresponding to the pins of the memory chip interface projecting from the back of the mainboard, the conductive posts configured to detachably connect with the pins of the memory chip interface, wherein the rheostat and the voltmeter are connectable to selected of the conductive posts.

2. The memory chip testing system of claim 1, wherein a portion of each conductive post is inserted in the insulating substrate, the portion comprises an open-ended hollow tube, with a pair of arcuate elastic strips set in the open-ended hollow tube and electrically connected with the conductive post, and the pair of elastic strips is configured to clamp one of the pins of the memory chip interface.

3. The memory chip testing system of claim 1, wherein the conductive posts comprise first conductive posts and second conductive posts, the first conductive posts are taller than the second conductive posts, and the first conductive posts are configured to electrically connect with either or both of the rheostat and the voltmeter.

4. The memory chip testing system of claim 1, wherein the conductive posts comprise first conductive posts and second conductive posts, the first conductive posts and the second conductive posts have the same height, and the first conductive posts are configured to electrically connect with either or both of the rheostat and the voltmeter.

5. A connector for use in a memory chip testing system, the memory chip testing system comprising a mainboard, the connector comprising:
an insulating substrate; and
a plurality of conductive posts secured to the insulating substrate and arranged corresponding to an arrangement of pins of a memory chip interface projecting from a back of the mainboard, the conductive posts configured to detachably connect with the pins of the memory chip interface.

6. The connector of claim 5, wherein a portion of each conductive post is inserted in the insulating substrate, the portion comprises an open-ended hollow tube, with a pair of arcuate elastic strips set in the open-ended hollow tube and electrically connected with the conductive post, and the pair of elastic strips is configured to clamp one of the pins of the memory chip interface.

7. The connector of claim 5, wherein the conductive posts comprise first conductive posts and second conductive posts, the first conductive posts are taller than the second conductive posts, and the first conductive posts are configured to electrically connect with either or both of a rheostat and a voltmeter.

8. The connector of claim 5, wherein the conductive posts comprise first conductive posts and second conductive posts, the first conductive posts and the second conductive posts have the same height, and the first conductive posts are configured to electrically connect with either or both of a rheostat and a voltmeter.
